(19) United States
(12) Patent Application Publication
(10) Pub. No.: US 2010/0128510 A1
(43) Pub. Date: May 27, 2010

(54) Magnetic Data Storage

(75) Inventor: Russell Paul Cowburn, London (GB)

Correspondence Address: MCDONNELL BOEHNEN HULBERT & BERGHOFF LLP, 300 S. WACKER DRIVE, 32ND FLOOR, CHICAGO, IL, 60606, US

(73) Assignee: INGENIA HOLDINGS (UK) LIMITED, London (GB)

(21) Appl. No.: 12/618,398

(22) Filed: Nov. 13, 2009

Related U.S. Application Data
(60) Provisional application No. 61/114,324, filed on Nov. 13, 2008.

(30) Foreign Application Priority Data
Nov. 13, 2008 (GB) 0820844.9

(51) Int. Cl. G11C 19/00; G11C 11/00

(52) U.S. Cl. 365/80; 365/158

(57) ABSTRACT

The present invention can provide a magnetic memory structure comprising a column comprising a plurality of layers of magnetic material, each sized to adopt a single magnetic domain state, and a plurality of layers of non-magnetic material arranged as spacer layers between adjacent ones of the layers of magnetic material, such that successive magnetic layers in the column are magnetically antiparallel coupled. The column is arranged to maintain therein a plurality of stable transitions of an order parameter of the magnetisations between the magnetic layers, the transitions having a chirality. This enables a single magnetic column structure to store multiple data bits in such a way as to enable the bits to be propagated through the column to enable sequential reading and/or writing of data in the column.

### FIELD

The present invention relates to a magnetic storage device and method and, in particular but not exclusively, to a magnetic data storage device and method utilising magnetic coupling between layers of synthetic antiferromagnets to maintain an introduced chiral soliton.

### BACKGROUND

In digital memory technologies, the major group of non-volatile memory devices use FLASH memory which typically uses charges floating in an oxide layer to provide data bit storage facilities. FLASH is known to have a number of drawbacks in terms of power requirements, slow read/write times and a limited maximum read/write lifecycle.

On account of the drawbacks of FLASH and similar electronic technologies, there have been proposed a number of techniques for magnetic memory devices, such as magnetoresistive RAM (“MRAM”). A number of MRAM techniques have been described in the literature, including the following.

U.S. Pat. No. 7,226,796 describes synthetic antiferromagnet structures for use in magnetic tunnel junctions in MRAM technology.

U.S. Pat. No. 6,898,112 describes a synthetic antiferromagnetic structure for magnetoelectronic devices.

“Magnetic Domain-Wall Racetrack Memory”, S. S. P. P. Parkin, M. Hayashi, L. Thomas, Science 320, 190 (2008); and U.S. Pat. Nos. 6,834,005, 6,898,132, 6,920,062, 7,031,178, and 7,236,386 describe different examples of a 3-dimensional non-volatile data storage device based on magnetic domain walls moving up shift registers comprising vertical tracks of magnetic material. All of the arrangements presented in these documents use spin transfer to propagate the domain walls. This technology does not use synthetic antiferromagnets at all, rather it uses a shift register arrangement for propagation of magnetic domains.

“Room temperature magnetic quantum cellular automata”, R. P. Cowburn, M. E. Welland, Science 287, 1466-1468 (2000) and “Magnetic nanodots for device applications”, R. P. Cowburn, Journal of Magnetism and Magnetic Materials. 242, 505-511 (2002) describe a soliton on a chain of magnetostatically parallel coupled ferromagnetic disks arranged adjacent one another in a single plane. This technology provided no synchronous mechanism for propagation, no possibility of putting a stream of bits in the same conduit, and no mechanism for unidirectional propagation of data.

PCT patent application publication no WO2002/041492 describes two systems: one is domain wall logic using magnetic nanowires, the other is the quantum cellular automata system described in Science 287, 1466-1468 (2000) mentioned above using magnetostatically coupled dots carrying a soliton.

Probing antiferromagnetic coupling between nanomagnets, R. P. Cowburn, Phys. Rev. B 65, 092409 (2002) describes chains of magnetostatically coupled ferromagnetic disks with an anisotropy. One of the conclusions of this work was that data could not be reliably propagated over any significant distance because the driving force decayed away. As with the other Cowburn works mentioned above, the disks were in the same plane.

U.S. Pat. No. 6,531,723 describes a magnetoresistance random access memory for improved scalability. This document introduces what is now known as “Toggle MRAM”. The document describes an MRAM cell with a synthetic antiferromagnet of N layers to hold a single data bit. This arrangement provides increased switching volume leading to improved scalability.

U.S. Pat. No. 6,545,906 describes a method of writing to a scalable magnetoresistance random access memory element. This has the same inventors as U.S. Pat. No. 6,531,723 and describes how a localised rotating field for the above N-layered SAF stack can be produced by delaying the current pulses through orthogonal word and bit lines.

Parish M C B, Forshaw M, IEE Proceedings-Circuits Devices and Systems 151 (5) 480-485 showed in a figure six repeat layers of a synthetic antiferromagnet, including ellipticity to create anisotropy, in the context of quantum cellular automata, as in Science 287, 1466-1468 (2000) mentioned above. The focus of this part of the paper is on keeping the layers coupled antiferromagnetically without error. The disclosure is thus very similar to Phys. Rev. B 65, 092409 (2002) mentioned above.

Property variation with shape in magnetic nanoelements, R. P. Cowburn, Invited Topical Review, J. Phys. D 33, R1-R16 (2000); Lateral interface anisotropy in nanomagnets, R. P. Cowburn, D. K. Koltsov, A. O. Adeyeye, M. E. Welland J. Appl. Phys. 87, 7067-7069 (2000) and Superparamagnetism and the future of magnetic random access memory, R. P. Cowburn, J. Appl. Phys. 93, 9310 (2003), all provide examples of elliptical single layer magnetic structures to create shape anisotropy.

### SUMMARY

The present invention has been conceived in the knowledge of limitations and drawbacks in conventional systems.

Accordingly, viewed from a first aspect, the present invention can provide a magnetic memory element structure comprising a plurality of layers of ferromagnetic material interspaced with non-magnetic layers. Each layer may be a disc which is small enough for the whole disc to adopt a single magnetic domain state. This forms a stack of what can effectively be considered as longitudinally overlapping antiferromagnets. This stack can maintain therein one or more introduced magnetisation direction frustrations where the antiparrallel coupling between successive magnetic layers is reversed, forming a chiral soliton. The introduced chiral solitons can be moved up and down the stack using an applied magnetic field, thus providing for the storage of multiple solitons per stack, thus providing in turn for the storage of multiple bits per stack.

This arrangement advantageously provides for the storage of multiple bits per memory cell, which in turn provides for a very high data density per substrate area. This, combined with the low power requirements and high read/write lifecycle of such a structure, allows the creation of a small size, high capacity, efficient memory device.

Particular features of some arrangements provide for propagation of a chiral topological soliton through a column of non-coplanar magnetostatically coupled magnetic disks. In some arrangements, such a soliton can be propagated synchronously using a rotating magnetic field. In some arrangements, such propagation does not require the presence of a structural propagation control element such as a NOT gate.

Particular aspects can provide a magnetic memory structure comprising a column of overlapping synthetic antiferromagnets configured to maintain a plurality of stable chiral disturbances in magnetisation direction between layers. Each chiral disturbance results in a reversal of an order parameter describing the alignments of the magnetic domains of the synthetic antiferrromagnets. Thereby, a plurality of data bits can be stored in the column by using the disturbances as domain walls between regions having different order parameters.

A corresponding method of storing data can comprise introducing plurality of stable chiral disturbances in magnetisation direction between layers into a column of overlapping synthetic antiferromagnets. Each chiral disturbance results in a reversal of an order parameter describing the alignments of the magnetic domains of the synthetic antiferrromagnets.

Viewed from one aspect, the present invention can provide a magnetic memory structure comprising a column comprising a plurality of layers of magnetic material, each sized to adopt a single magnetic domain state, and a plurality of layers of non-magnetic material arranged as spacer layers between adjacent ones of the layers of magnetic material, such that successive magnetic layers in the column are magnetically antiparallel coupled. The column is arranged to maintain therein a plurality of stable transitions of an order parameter of the magnetisations between the magnetic layers, the transitions having a chirality. This enables a single magnetic column structure to store multiple data bits in such a way as to enable the bits to be propagated through the column to enable sequential reading and/or writing of data in the column.

In some examples, the transitions create a plurality of regions within the column, each region having an order parameter opposite to the order parameter of an adjacent region. This effect is caused by the presence of the transitions and the impact of an order parameter transition between two adjacent rejoins.

In some examples, the column can comprise between 100 and 100,000 magnetic layers. Thus a very large storage element capable of storing may tens, hundreds or thousands of bits can be provided.

In some examples, each transition is a soliton. The soliton can be a topological soliton, and the topological soliton can be a kink soliton. Such solitons can be thought of as domain walls between separate magnetic domains or regions.

An arrangement operable to introduce a transition into the column can be provided. The arrangement comprises a charge pulse conduit arranged parallel and adjacent to an end magnetic layer in the column operable to carry an electrical charge pulse therethrough. The arrangement can also comprise a drive element operable to cause a charge pulse to travel through the charge pulse conduit whilst a rotating magnetic field is applied to the column.

An arrangement operable to read a reversal from the column can be provided. The arrangement to read a reversal can use at least one of a giant magneto resistance spin valve, a tunnel magento resistance structure, and a magnetic tunnel junction stack. In some examples, the arrangement to read a reversal can be arranged such that the transition is maintained in the column after reading thereof.

In some examples, the memory structure can be operable as a first in first out shift register and/or as a first in last out shift register.

In some examples, the magnetically antiparallel coupling between successive magnetic layers in the column causes the magnetisations of successive magnetic layers in the column to be antiparallel aligned except where the alignment is forced to be non-antiparallel by the presence of a transition. The lowest energy state of successive magnetic layers in the column is one of antiparallel coupling, so this state is adopted unless the presence of a transition forces a higher energy state to be maintained.

Viewed from another aspect, the present invention can provide a magnetic memory circuit comprising at least one memory structure as previously discussed and a signal supply conduit operable to carry a write signal to or read signal from the structure. Thus a memory using the memory structure can be provided.

In some examples, a plurality of memory structures are provided and the signal supply conduit comprises an arrangement to address individual ones of the plurality of structures. Thus a high density memory device can be provided using a number of memory structures with each memory structure being usable independently of the others.

Viewed from a further aspect, the present invention can provide a magnetic memory device comprising a magnetic memory circuit as previously discussed and a magnetic field generator operable to generate a rotating magnetic field. Thus a combined device capable of both holding stored bits and reading and writing those bits can be provided.

In some examples the magnetic field generator comprises a configuration to supply a field inducing signal to the signal supply conduit.

In some examples the magnetic field generator comprises a pair of current carrying conductors oriented substantially orthogonally to one another.

Viewed from another aspect, the present invention can provide a method of storing data within a column comprising a plurality of layers of magnetic material, each sized to adopt a single magnetic domain state, and a plurality of layers of non-magnetic material arranged as spacer layers between adjacent ones of the layers of magnetic material; such that successive magnetic layers in the column are magnetically antiparallel coupled. The method can comprise introducing into the column a plurality of stable transitions of an order parameter of the magnetisations between the magnetic layers, the transitions having a chirality.

In some examples, the data can be encoded using one of: an order parameter state, or a presence or absence of an order parameter transition to represent data values.

In some examples, the column can comprise between 100 and 100,000 magnetic layers.

In some examples, each transition is a soliton. The soliton can be a topological soliton, and the topological soliton can be a kink soliton. Such solitons can be thought of as domain walls between separate magnetic domains or regions.

In some examples, the method further comprises introduce a transition into the column by passing a charge pulse through a charge pulse conduit arranged parallel and adjacent to an end magnetic layer in the column.

In some examples, the method further comprises reading a transition from the column using at least one of a giant magneto resistance spin valve, a tunnel magento resistance structure, and a magnetic tunnel junction stack. In some examples, the method further comprises maintaining the transition in the column after reading.

In some examples, the further comprises operating the column as a first in first out shift register and/or a first in last out shift register.

In some examples, the method further comprises applying an externally generated rotating magnetic field to the column to cause propagation of chiral disturbances along the column.

In some example, the method further comprises generating the rotating magnetic field using a pair of current carrying conductors oriented substantially orthogonally to one another.

In some examples, the magnetically antiparallel coupling between successive magnetic layers in the column causes the magnetisations of successive magnetic layers in the column to be antiparallel aligned except where the alignment is forced to be non-antiparallel by the presence of a transition. The lowest energy state of successive magnetic layers in the column is one of antiparallel coupling, so this state is adopted unless the presence of a transition forces a higher energy state to be maintained.

Viewed from another aspect, the present invention can provide an apparatus comprising a stack of magnetically antiparallel coupled magnetic elements configured to maintain a chiral soliton in magnatisation direction therein.

Viewed from a further aspect, the present invention can provide an apparatus comprising a stack of overlapping synthetic antiferromagnets configured to maintain a chiral soliton therein.

Compared to previous magnetic shift register designs, arrangements of the present invention additionally advantageously allow for synchronous propagation of data in magnetic form without the use of a NOT gate structure.

### BRIEF DESCRIPTION OF THE FIGURES

Specific embodiments of the present invention will now be described by way of example only with reference to the accompanying figures in which:

FIG. 1 shows schematically a synthetic antiferromagnet;

FIGS. 2A and 2B show schematically two stable states of a synthetic antiferromagnet;

FIG. 3 shows a synthetic antiferromagnet comprising a large number of repeat layers;

FIG. 4 shows schematically regions of opposite order parameter;

FIG. 5 shows schematically a finite width soliton;

FIG. 6 shows schematically a narrow soliton;

FIG. 7 shows a broad soliton;

FIGS. 8A and 8B show schematically two oppositely handed solitons of the same energy;

FIG. 9 shows a graph describing the finite extent of a chiral soliton;

FIGS. 10A to 10E shows schematically the propagation of a soliton during a complete cycle of applied rotating field;

FIGS. 11A to 11G show schematically the propagation of a soliton during 7 cycles of applied rotating field;

FIG. 12 shows a graph describing soliton width as a function of ellipticity of the magnetic disk;

FIG. 13 shows a graph of nucleation, propagation and maximum propagation fields for a soliton stack;

FIG. 14 shows a graph showing annihilation field reduction by end-zoning;

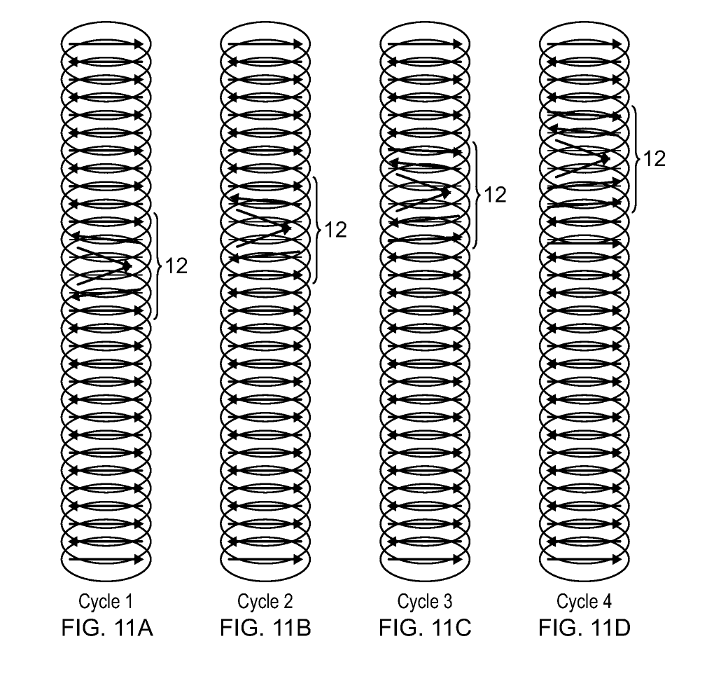

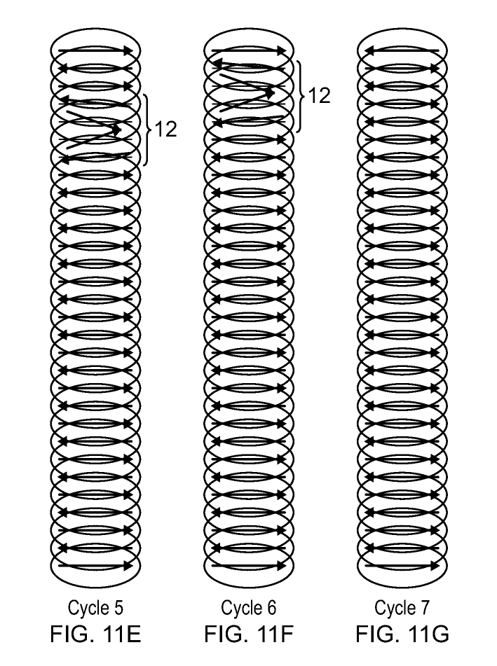

FIG. 11 shows schematically a data storage device;

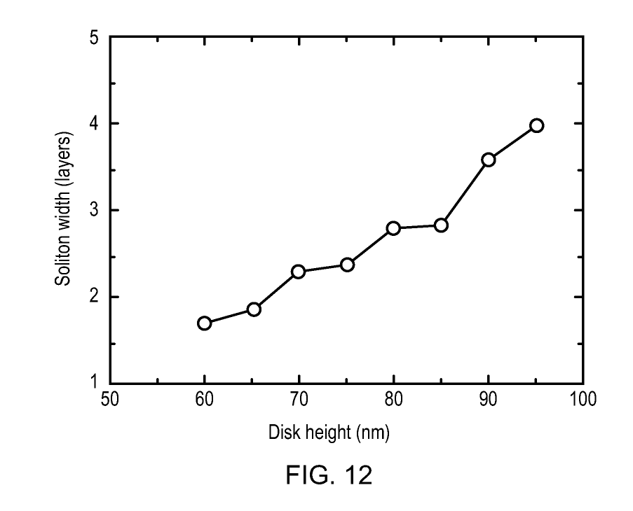

FIG. 12 shows schematically a soliton injector;

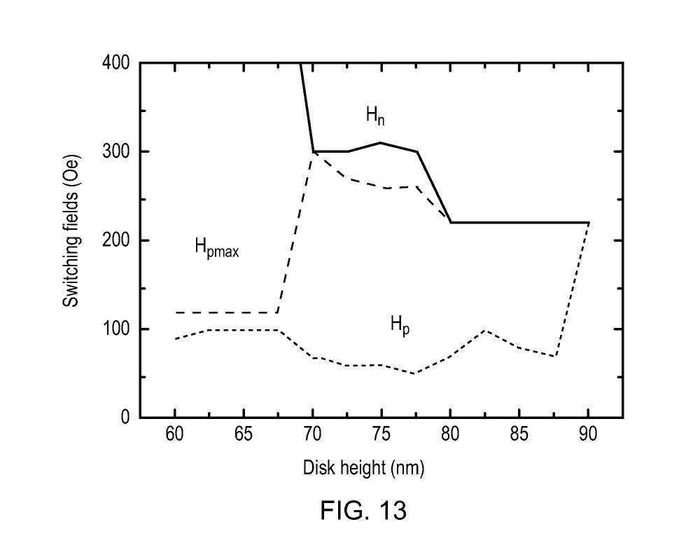

FIG. 13 shows a phase diagram for chiral soliton injection;

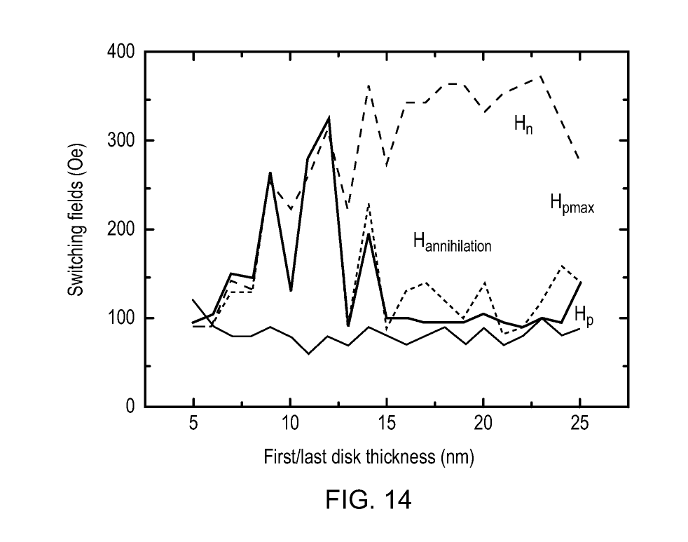

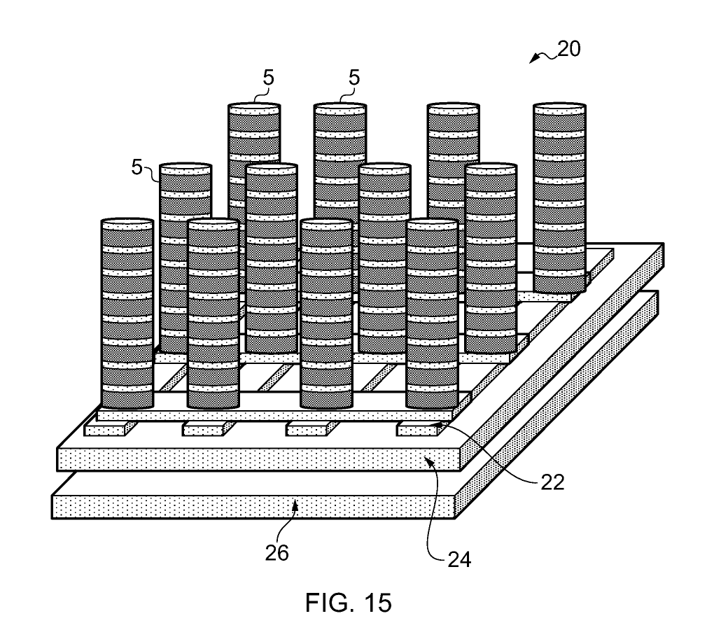

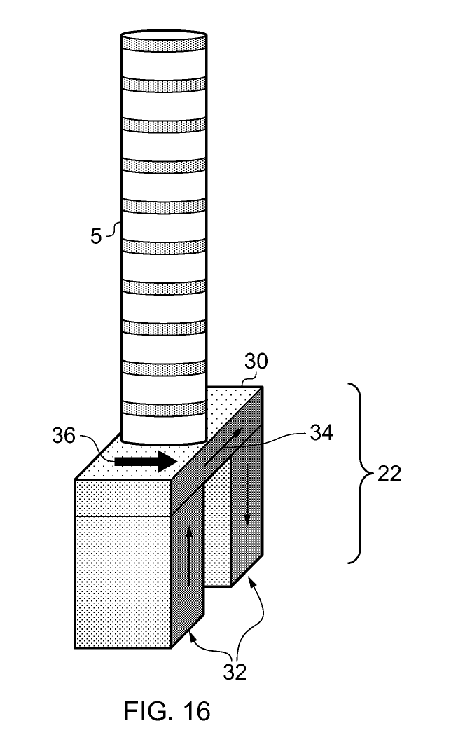

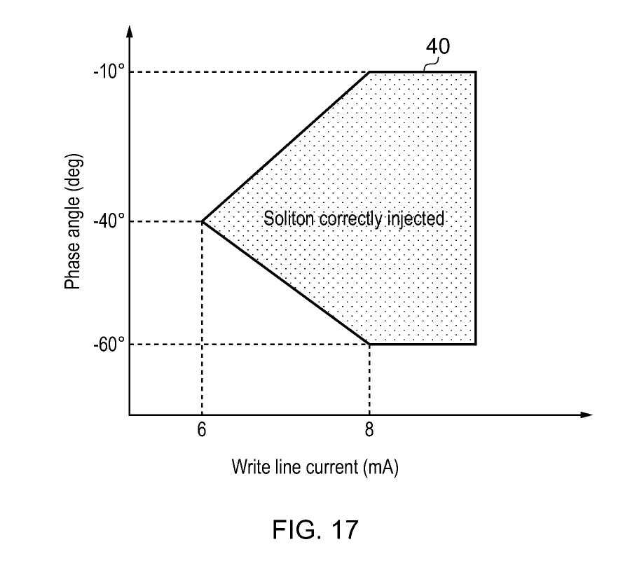

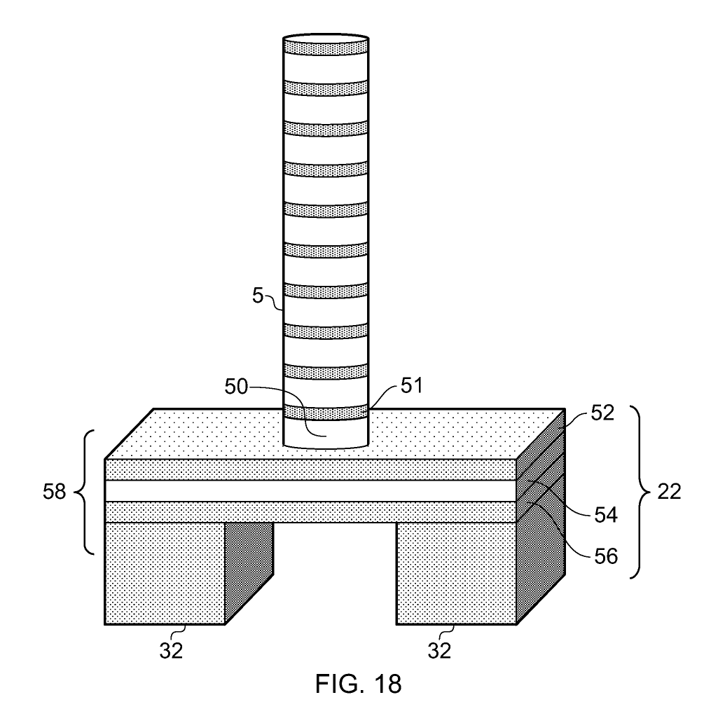

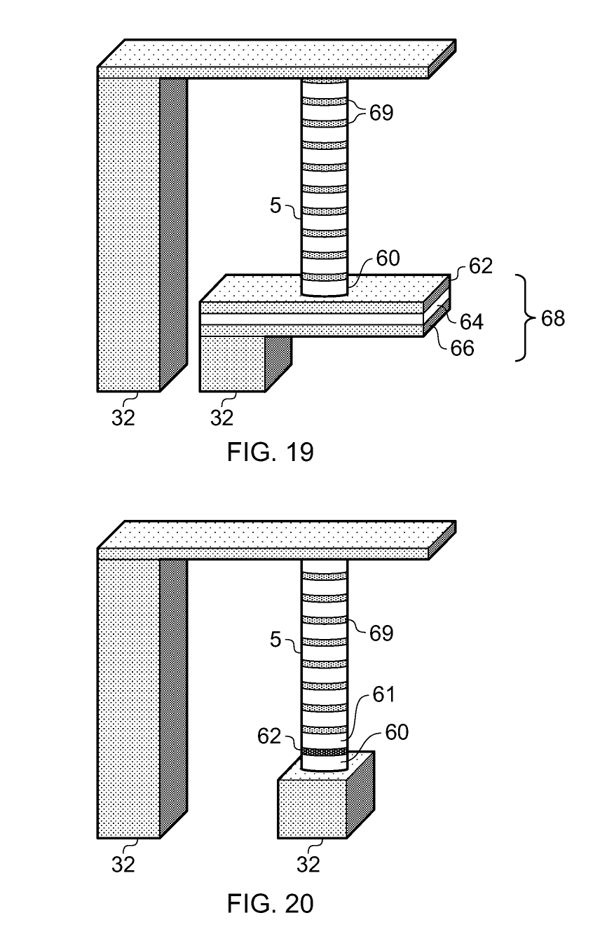

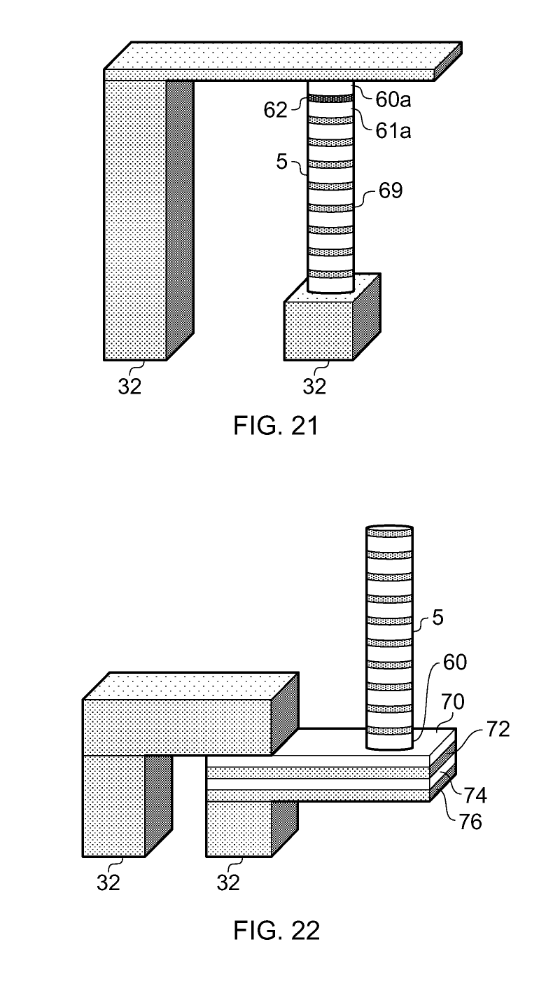

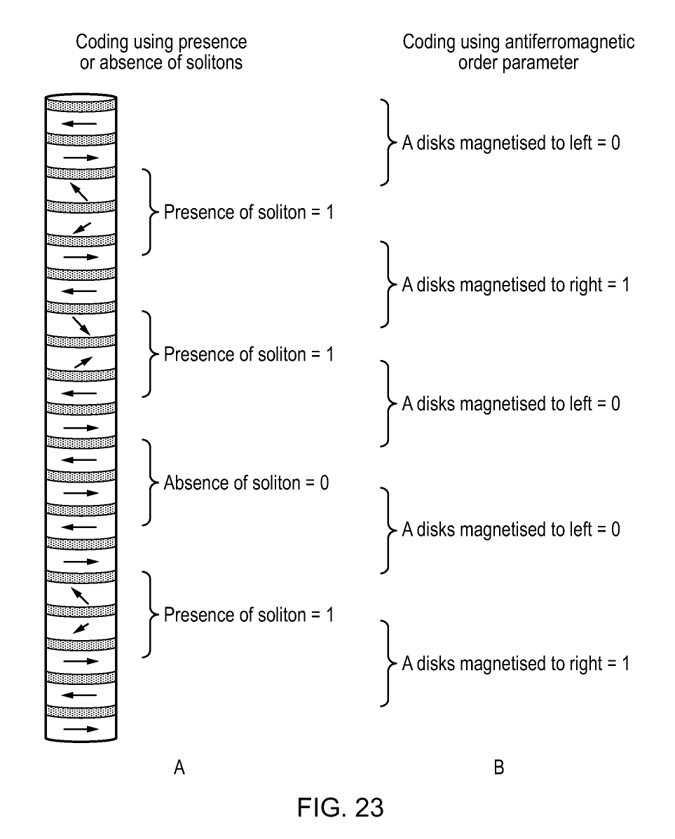

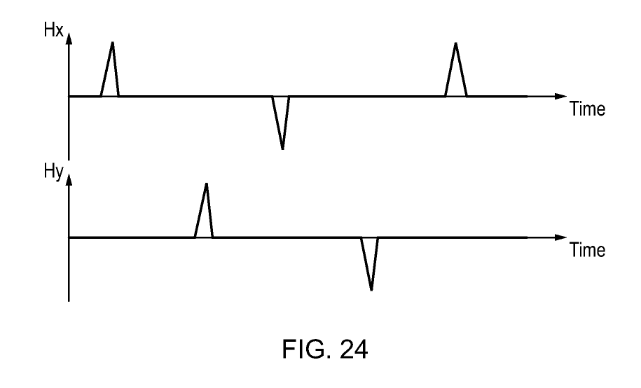

FIG. 14 shows schematically a spin valve based read-out detector;

FIG. 15 shows schematically a TMR based soliton detector;

FIG. 16 shows schematically another TMR based soliton detector;

FIG. 17 shows schematically another TMR based soliton detector;

FIG. 18 shows schematically an MTJ bases soliton detector;

FIG. 19 shows schematically two different data coding schemes; and

FIG. 20 shows schematically pulsed externally applied orthogonal field components.

While the invention is susceptible to various modifications and alternative forms, specific embodiments are shown by way of example in the drawings and are herein described in detail. It should be understood, however, that drawings and detailed description thereto are not intended to limit the invention to the particular form disclosed, but on the contrary, the invention is to cover all modifications, equivalents and alternatives falling within the scope of the present invention as defined by the appended claims.

### SPECIFIC DESCRIPTION

Particular examples to illustrate the operation of the present invention will now be described with reference to the Figures. The skilled reader will appreciate therefrom that the principles and concepts which underlie the present invention can be implemented in a variety of ways which may extend beyond the examples described herein. The present invention is therefore not limited by the disclosure of the specific examples, and rather is limited only by the spirit and scope of the appended claims.

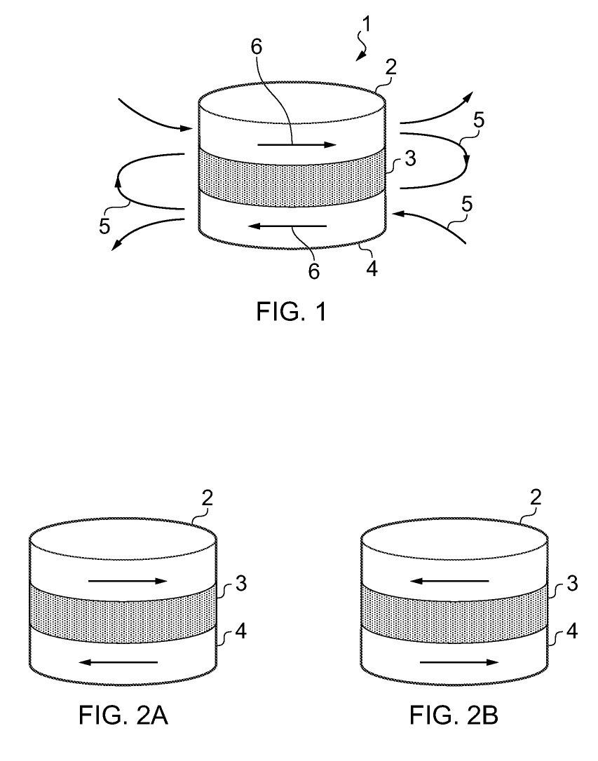

FIG. 1 illustrates a so-called ‘synthetic antiferromagnet’ or SAF 1, which comprises two magnetic nanodisks 2 and 3 separated by a non-magnetic spacer layer 4. The dipolar fields (shown by the curved arrows 5 in FIG. 1) from the two magnetic disks cause the magnetisation in the two magnetic disks to align anti-parallel (as shown by the straight arrows 6 in FIG. 1).

SAFs can be used in magnetic random access memory (MRAM) devices, usually with two current-carrying strip lines running above and below the SAF to generate local magnetic fields which switch the SAF between its two stable magnetic states. The stable states of a SAF are shown in FIG. 2, with FIG. 2A showing a first state wherein the magnetisation of the upper magnetic disc 2 is oriented in a first direction and the magnetisation of the antiparellel coupled lower disc 4 is oriented in a second, opposite direction. FIG. 2B shows a second state wherein the magnetisation of the upper magnetic disc 2 is oriented in the second direction and the magnetisation of the antiparellel coupled lower disc 4 is oriented in the first direction. These two states can be used to store the binary states 1 and 0, and hence a single-bit non-volatile memory element can be formed.

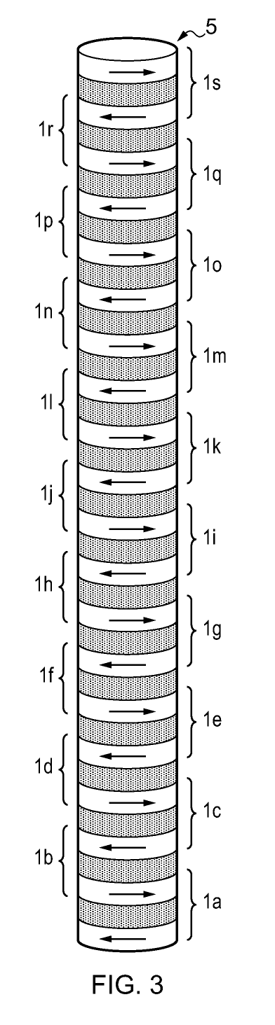

FIG. 3 shows a SAF stack 5 made from a large number of repeat layers of magnetic/non-magnetic materials. As illustrated in FIG. 3, the stack or column form SAF 5 is effectively made up from a large number of overlapping SAFs of the type illustrated in FIG. 1, labelled as 1a to 1s in FIG. 3. As will be appreciated, for the SAF to function as such, each magnetic disk should be small enough for the disk to adopt a single magnetic domain state. The magnetisation directions shown in FIG. 3 is the lowest energy state for this stack, i.e. each magnetic disk magnetises anti-parallel to its two nearest neighbours.

According to the present examples, in order to make most efficient use of a large SAF 5 such as that show in FIG. 3, and to enable the storage of multiple bits per SAF, the orientations of the magnetisations in different parts of the SAF are altered relative to one another.

To enable an understanding of how this can be achieved, it is helpful to consider the magnetic discs of the SAF as belonging to two families, A and B. Alternate discs belong to different families, such that each member of family A is separated from the next member of family A by a member of family B. In the configuration shown in FIG. 3 the A-disks are magnetised to the right and all of the B-disks are magnetised to the left. The stack could however have been drawn with all of the A-disks are magnetised to the left and all of the B-disks are magnetised to the right. There is thus an order parameter associated with the stack, which is now arbitrarily defined as having value 1 when in the configuration of FIG. 3 and value −1 when in the opposite configuration.

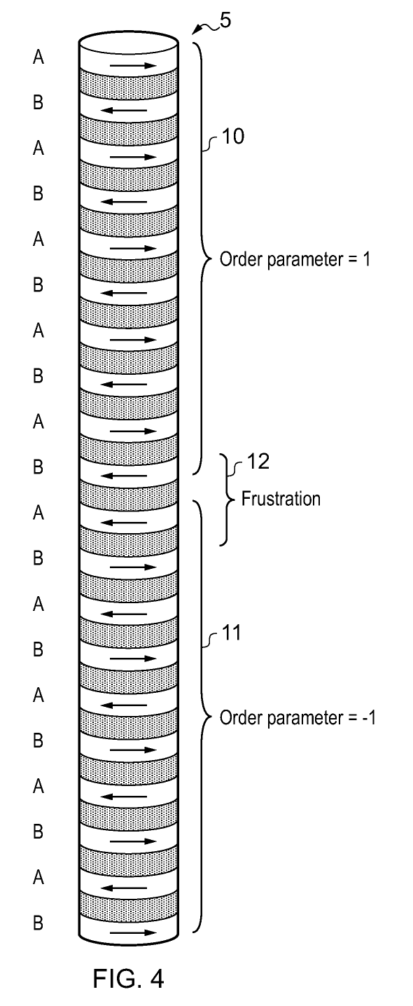

Now, if there is a stack or SAF 5 in which the top half of disks 10 are configured with the order parameter equal to 1 and the bottom half 11 are configured with the order parameter equal to −1, as shown in FIG. 4, a frustration 12 is introduced.

Away from the centre of the stack, each magnetic disk is in a low-energy environment, i.e. each of its two nearest neighbours are magnetised anti-parallel to itself. At the very centre of the stack, however, where the two regions of different order parameter meet, there are two magnetic disks which are in a frustrated state—each has one neighbour that is magnetised parallel to it (high energy) and one neighbour that is magnetised anti-parallel to it (low energy). If one of the frustrated disks were to have its magnetisation reversed, then the other frustrated disk would no longer be frustrated, but instead the frustration 12 would move up or down by one magnetic disk and a previously unfrustrated disk would now be frustrated. This region of frustration 12 is:
mobile (by reversing the magnetisation of a frustrated disk);
localised (away from the frustration each disk is in a stable, low-energy state);
persistent (to remove the frustration, half of the disks in the stack would have to be reversed, equivalent to moving the frustration all the way to one end of the stack and allowing it to fall out of the end).

These are the general condition for a topological soliton. It is a kink soliton as the order parameter changes in passing through the soliton.

A general discussion of topological magnetic solitons can be found in “Dynamics of Topological Magnetic Solitons, experiment and theory” V. G. Bar'yakhtor, M. V. Chetkin, B. A. Ivanov, S. N. Gadetskii, Springer Tracts in Modern Physics, Vol. 129, 1994, ISBN 3-540-56935-9 and 0-387-26935-9.

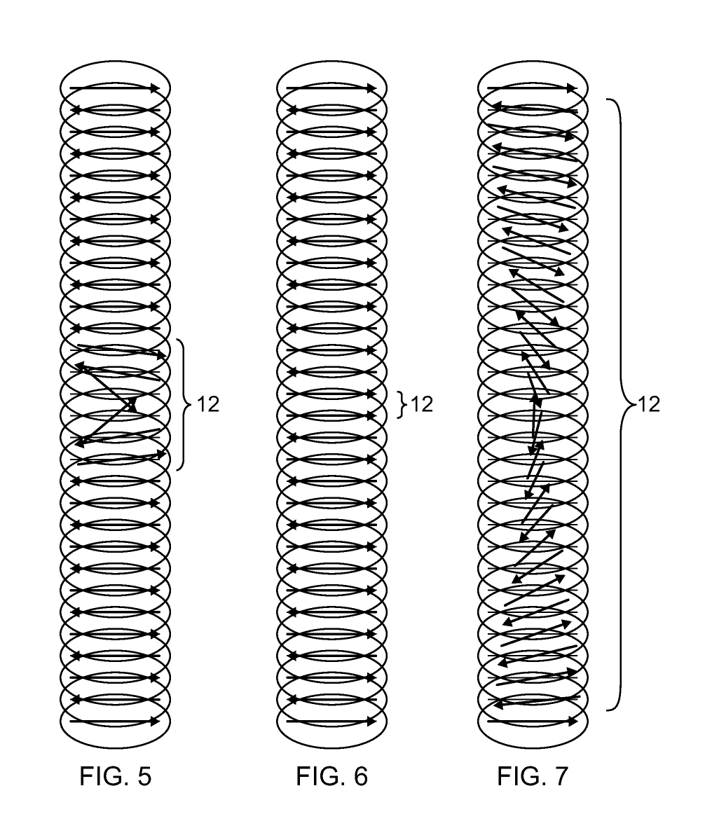

The magnetic configuration shown in FIG. 4 is not necessarily stable. Depending on the relative values of the anisotropy and the strength of magnetic coupling between disks, it may be possible for the system to lower its energy by increasing the number of disks over which the frustration 12 is shared. FIG. 5 shows an example which is energetically stable, calculated by Monte Carlo modelling of macrospins. In this case, the anisotropy strength and the coupling strength are of comparable size, which results in the frustration 12 being shared across 6 disks, with approximately 90 degrees between the magnetisations at the centre of the frustration 12. Such a soliton has a finite width.

If the anisotropy is much stronger than the coupling strength, then solitons of finite width (FIG. 6) are energetically discouraged because the magnetisation in the centre of the soliton is aligned with the hard axis of the anisotropy, leading to a high energy state. In this case, it is energetically preferable for the transition from one order parameter phase to the other to be made as abruptly as possible. As shown in FIG. 6 where the frustration is shared over zero disks, so that the soliton has a width of only 2 disks.

On the other hand, if the magnetic coupling between disks is much stronger than the anisotropy, then the soliton becomes very extended as there is little energy penalty for magnetisation meaning that the anisotropy easy axis and the coupling energy can be minimised by spreading the frustration across as many disks as possible. FIG. 7 shows an example of an energetically stable configuration for this case, where the frustration 12 is spread over the maximum number of available disks.

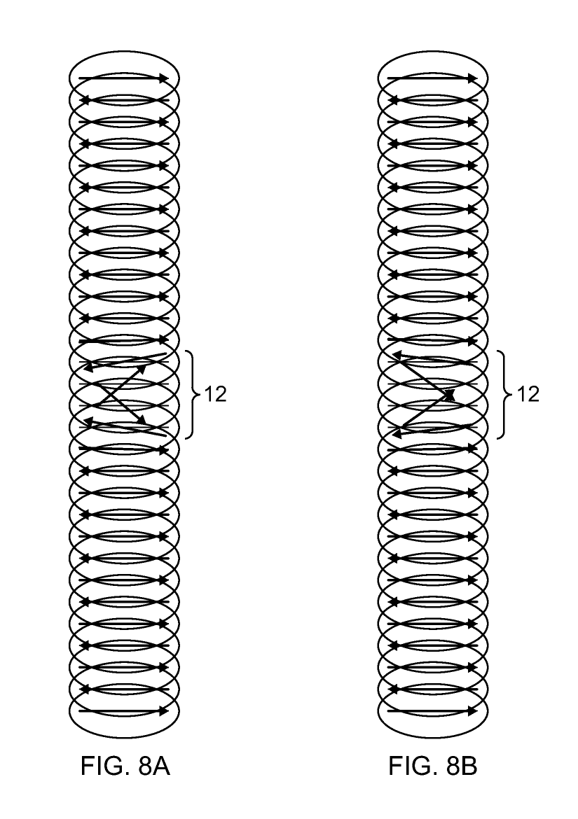

The solitons explained with reference to FIGS. 5 and 7 are useful in the context of the presently described examples as they are chiral, i.e. they have a handedness. This is most clearly illustrated in FIG. 7 where the soliton is very wide. In FIG. 7, the axis of the magnetisation (ignoring the direction along that axis) is clearly seen to rotate clockwise from the top of the stack to the bottom. Such a soliton would conventionally be referred to as being right-handed. In the described examples, a stack SAF can support both left-handed and right-handed solitons and these two options are usually energetically degenerate, i.e. neither is preferred over the other. The soliton chirality is selected at the time of generation of the soliton and is usually then preserved, i.e. the soliton cannot easily change chirality. FIG. 8 shows results from Monte Carlo macrospin modelling in which a right handed and left handed soliton of the same anisotropy/coupling strength are shown. The soliton in FIG. 8A is left-handed and the soliton in FIG. 8B is right-handed. Only the very narrowest soliton, such as that shown in FIG. 6, is not chiral, since the transition from one order parameter to the other occurs over such a short distance that a rotation sense cannot be defined.

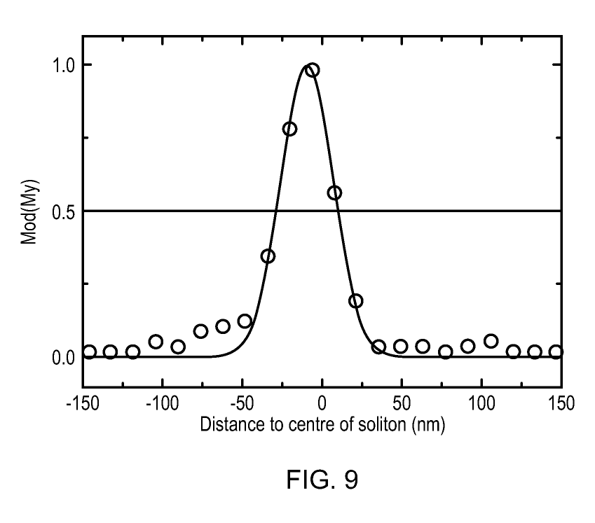

FIG. 9 shows the finite extent of a chiral soliton similar to that illustrated in FIG. 6 by showing the magnitude (i.e. without sign) of the component of magnetisation in the plane of the disk and transverse to the magnetic easy axis (i.e. along the anisotropy hard axis). The physical parameters in this case are: disk width 100 nm, disk height 80 nm, disk thickness 10 nm, spacer thickness 4 nm, magnetic material permalloy.

An important feature of these chiral solitons, is that they can be propagated (i.e. moved) along (up and down) the stack by an externally applied magnetic field which rotates in the plane of the disks. The motion is synchronous with the rotating field, the soliton moving by 2 magnetic disks for each cycle of rotating field. The direction of propagation (i.e. up the stack or down the stack) depends on the relative chirality of the soliton and the externally applied rotating magnetic field. Table 1 summarises the four possible combinations. As the left- and right-handed solitons are mutually inverse, a pair of oppositely-handed solitons can, if propagated into one-another by an applied field, cancel one-another out resulting in mutual annihilation of both solitons.

TABLE 1
Soliton propagation directions

| Soliton chirality¹ | Rotating field chirality² | Propagation direction |
|---|---|---|
| Right-handed | Anti-clockwise | Down |
| Right-handed | Clockwise | Up |
| Left-handed | Anti-clockwise | Up |
| Left-handed | Clockwise | Down |

¹As defined in FIGS. 8A and 8B
²As viewed from above

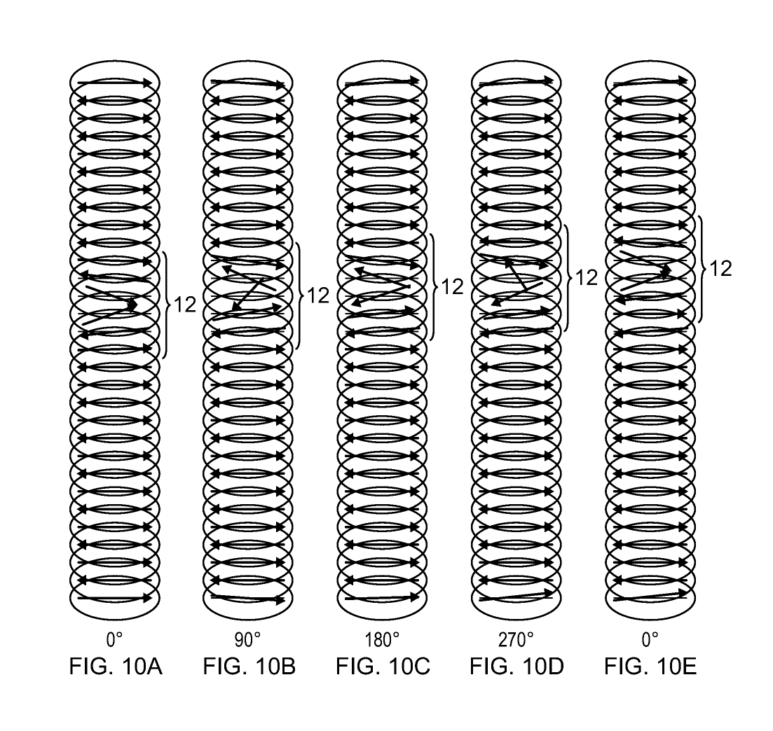

FIGS. 10A to 10E show an example of a right-handed soliton propagating under a clockwise externally applied rotating field, as calculated by Monte-Carlo macrospin modelling. A snapshot of the model has been taken every quarter cycle of applied field—FIG. 10A shows an applied field orientation at the start position (i.e. zero rotation), FIG. 10B shows an applied field at an orientation of 90°, FIG. 10C shows an applied field at an orientation of 180°, FIG. 10D shows an applied field at an orientation of 270°, and FIG. 10E shows an applied field at an orientation of 360° (which is the same as zero degrees). It can seen from FIG. 10 that after one complete cycle of rotating field, the magnetisation vectors are back to where they started from (forming a V-shape, pointing to the right), except that the soliton is now two disks higher in the stack than previously.

FIGS. 11A to 11G show a sequence with a snapshot taken every cycle of field. The soliton can be seen to climb to the top of the stack (at a rate of two disks per 360 degree rotation cycle of the applied field and then “fall out” of the top of the stack (a process called annihilation).

As discussed above with reference to FIGS. 5, 6 and 7, the width of the soliton is determined by the relative strengths of the anisotropy and the inter-disk coupling strength. This is analogous to the way in which the width of a magnetic domain wall in a continuous magnetic material (another type of magnetic soliton) is determined by the relative strength of the anisotropy and the exchange coupling.

There are two ways in which the anisotropy required to stabilise a finite width chiral soliton may be generated: shape anisotropy and magnetocrystalline anisotropy. To use shape anisotropy, the stack of disks should be made to have an elliptical cross section. This will generate a uniaxial anisotropy with easy axis directed along the long axis of the ellipse. The strength of the anisotropy field is a function of the thickness of the magnetic layers and the extend of the ellipticity (i.e. how far removed the disk is from a circle). Magnetocrystalline anisotropy includes two sub-options for implementation. The first is to choose a material having magnetic layers which possesses an intrinsic anisotropy. The second is to impose anisotropy on the material by growing it in the presence of a strong magnetic field (a technique described in Gentils, A, Chapman, J N, Xiong, G, et al, Variation of domain-wall structures and magnetization ripple spectra in permalloy films with controlled uniaxial anisotropy, J APPL PHYS, 2005, Vol: 98, ISSN: 0021-8979) or at an oblique deposition angle (a technique described in U.S. Pat. No. 6,818,961). The examples described herein are based upon uniaxial symmetry and all references to modelled data use this approach. However, both other forms of shape anisotropy and various forms of shape anisotropy can also be used to create similar or identical results.

The inter-layer coupling can be achieved using two approaches: magnetostatic interactions and RKKY (Ruderman-Kittel-Kasuya-Yosida) exchange interactions. It is to be expected that magnetostatic interactions will always be present, regardless of whether RKKY is also a factor. For RKKY to significantly contribute to the inter-layer coupling, the non-magnetic layer must be extremely thin (typically 2-6 atomic monolayers). If RKKY is to be substantially excluded and only magnetostatic interactions to be used, then the non-magnetic spacer layer should be made greater than or equal to 3 nm in thickness, as at this thickness the RKKY interaction is largely suppressed and only the magnetostatic interaction remains. In practice, it does not matter what the physical source of the interlayer coupling is, rather it is the properties provided thereby that are important. Desirable properties for the inter-layer coupling include: (i) being of the correct strength to balance the chosen anisotropy strength to give a compact (restricted width) but still chiral soliton; (ii) being reproducible in manufacture; and (iii) favouring anti-parallel alignment of neighbouring magnetisation. It is the case that magnetostatic interactions always favour anti-parallel alignment. RKKY interactions can favour either parallel or anti-parallel, depending on the precise thickness of the non-magnetic spacer layer.

In some manufacturing processes, it can be easier to achieve a high level of reproducibility with thicker non-magnetic layers. In such circumstances, it may be preferred to have a non-RKKY implementation where magnetostatic interactions are substantially the only coupling mechanism in effect.

Thus it has now been described how a synthetic antiferromagnet can be produced in a multi-layered stack form and how that can hold one or more frustrations in magnetisation alignment, each of which frustrations give rise to a chiral soliton in the stack.

The physical dimensions of the disks can be used to control the soliton width within the stack. The anisotropy to coupling strength ratio can be controlled by changing the ellipticity of the magnetic disk. FIG. 12 illustrates this relationship between the soliton width and the ellipticity of the magnetic disk shape. In FIG. 12, the soliton width (expressed in repeat layers of SAF) is plotted as a function of the magnetic disk height (minor axis) for disk width 100 nm, disk thickness 10 nm, spacer thickness 4 nm, and magnetic disk material Permalloy.

It has been discovered that many of the concepts previously described for data storage and digital logic devices based on domain walls magnetic nanowires also apply to SAFs containing chiral solitons. When transferring these concepts between these very different physical structures, it can be seen that the SAF itself can be treated as analogous to the domain wall conduit (i.e. the nanowire) and the chiral soliton can be treated as analogous to the domain wall. Perhaps the most important portable concepts are those of propagation field (Hₚ) and nucleation field (Hₙ), which it has been discovered remain valid in the SAF/chiral soliton environment.

The propagation field is the minimum strength of externally applied rotating field that must be required before the soliton will begin to move. This is therefore a threshold value (i.e. more akin to “coercive field”) and not a physically applied field.

The nucleation field (also a threshold value) is the maximum strength of rotating field than may be applied externally before new solitons begin to nucleate spontaneously.

In order for a SAF stack to serve as a useful device, it is usually the case that the strength of the applied rotating field should be greater than the propagation field (so that propagation actually occurs) but lower than the nucleation field (so that additional solitons are not spontaneously generated). It can therefore be desirable to create a device that has a large range between these two threshold values.

If the applied field used for soliton propagation falls within the range between the propagation field and the nucleation field, any solitons that have been injected will be propagated up or down the stack, but the stack will not create new solitons of its own accord. The SAF stack is therefore a form of conduit that can be used to contain and move data where the data bits are coded using chiral solitons.

In addition to the propagation and nucleation fields, there are two further threshold fields that describe the behaviour of the SAF stack in terms of soliton storage and propagation. These are the maximum propagation field (H_{p max}) and the annihilation field (Hₐ).

The maximum propagation field relates to the width of the soliton within the SAF. Monte Carlo macrospin modelling shows that the soliton narrows slightly as the applied field strength is increased. If the applied field is too strong (but still less than the nucleation field) it may happen that the soliton becomes so narrow as to lose its chirality. In that case, it can no longer be propagated. Additionally, if the field were subsequently reduced the soliton could regain chirality but could do so with either the same or opposite handedness to the original chirality. Thus, while it is can be desirable to use an applied field strength higher than the propagation field in order to allow the soliton to push through any physical defects in its conduit, there is a maximum applied field strength that may be used before the soliton loses its chirality. In some cases (depending on the anisotropy and coupling strength) the maximum propagation field threshold is above the nucleation field and so is not relevant. In other cases, however, it is lower than the nucleation field and so becomes the limiting value for applied field strength instead of the nucleation field.

The annihilation field is the minimum applied field strength that will allow a soliton approaching the top or bottom of the SAF stack to push through the end and be annihilated. In some cases (depending on the anisotropy and coupling strength of the disks at the ends of the SAF stack), a soliton may experience a repulsive force as it approaches the ends of the SAF stack such that the normal propagation field is insufficient to annihilate the soliton out the end of the stack. The annihilation field can thus be thought of as an augmented propagation field that allows the soliton to move even at the ends of the SAF stack and ultimately out of the stack.

Using the Monte Carlo macrospin model mentioned above, some example values have been calculated for each of Hₚ, Hₙ, H_{p max} and Hₐ for different SAF stack structures. These values assume that there is no RKKY coupling (i.e. all interlayer coupling is magnetostatic). FIG. 13 shows a summary of the results. As can be clearly seen, there is a wide region (between approximately 70 nm and 85 nm height for this case) where there is a large separation between propagation field and nucleation field. It is in these regions of wide separation that the SAF stack acts as a good conduit for chiral solitons and hence useful devices.

The data in FIG. 13 plots the nucleation, propagation and maximum propagation fields for a soliton stack made from 10 nm thick, 100 nm wide Permalloy disks with a 4 nm thick spacer layer. Field strengths are in Oersteds (Oe). For a comparison to SI units, note that 1 Oe is defined as 1000/4π (≈79.5774715) amperes per metre of flux path.

As mentioned above, a soliton may experience a repulsive force as it approaches the ends of the SAF stack. In the presently described examples, it is possible to minimise this repulsive force (and hence achieve approximate equality between the annihilation field and the propagation field) by altering the thicknesses of the magnetic and non-magnetic layers close to the ends of the stack. This approach may be termed ‘end zoning’, and is functionally analogous to matching the impedance at the end of a transmission line by a gradual tapering of some electrical property. In practice, making alterations to the layer thickness is straightforward to achieve as layer thickness is usually determined by a material deposition time and does not change a lithography used for material deposition. End zoning can also be achieved by altering the ellipticity of the disks close to the ends of the SAF stack. It is however believed that this would be significantly more difficult to fabricate than the altered thickness approach as the lithography masks would need to be altered for the end zoned layers.

In the simplest case, end zoning can be performed by changing only the thickness of the first and last magnetic disks in the SAF stack. FIG. 14 shows how Hₐ is reduced by increasing or decreasing the thickness of the first and last magnetic disk. This approach of changing only the first or last disk in the stack can be referred to as end zoning.

Thus it will be understood that a SAF stack can be provided which can hold therein one or more chiral solitons, which solitons can be propagated in both directions along the stack by an applied magnetic field which rotates in the plane perpendicular to the length (or height) of the stack. It will also be understood that such solitons can be annihilated by propagation out of the stack and that the properties of the stack in propagation of solitons can be defined by a number of threshold field strengths.

Therefore, there will now be described various examples of how SAF stacks such as those described above can be used to implement a data storage device.

FIG. 15 shows a schematic of a data storage device using a number of SAF stacks 5. Most of the device can be formed using a Back End Of Line (BEOL) process on a CMOS chip 24. The number of repeat layers in each stack 5 governs the maximum data density in terms of number of data bits per stack. In practice, and so as to maintain the chirality of each frustration, a minimum of approximately 4 repeat layers are required per soliton, although more layers can be used per soliton if required. Although small height stacks can be used, it can be seen that taller stacks provide advantages of greater storage capacity per chip area. Therefore, in the following examples, the SAF stacks 5 may have as few as 100 repeat layers (providing a maximum data density of approximately 25 stored bits per stack) or, by using a suitable high aspect ratio fabrication process, as many as 100,000 layers (providing a maximum data density of 25,000 stored bits per stack).

At one end of each SAF stack 5 there is a soliton injector device 22 which converts electrical signals from the CMOS logic of the chip 24 into a stream of solitons representing a serial data stream that is to be stored in the SAF 5. At the same end (as shown) or the other end (not shown) of the SAF stack there is a detector device which is used during data retrieval to convert the magnetic state at the end of the SAF stack back into electrical pulses. An external applied field generator 26 can be operated to apply a magnetic field which rotates in the plane of the device and which can therefore drive solitons along each SAF stack 5.

The data storage device can be implemented with either a global field rotator (as shown in FIG. 15) or with local field generators for individual ones or groups of stacks 5. Where a filed is generated which affects more than one stack, any use of the filed to propagate solitons up or down those stacks will affect all of the driven stacks at once, leading to parallel propagation of solitons in the affected stacks.

As mentioned above, a data storage device can store data bits by injecting one or more solitons at one end of the stack and propagating them along the stack. The soliton(s) would then remain in the stack until required, at which point it would be either be propagated through to the other end of the stack and detected as it leaves (a First In First Out serial shift register) or the rotating field direction would be reversed and the data sequence would be propagated out of the same end that it was introduced, in reverse order (a First In Last Out serial shift register).

In either case, it is necessary to inject controllably at one end of the stack a sequence of solitons representing the data bits to be stored. The coding mechanisms that could be used are discussed below with reference to FIG. 23. In the present examples, it is most likely that the data sequence for storage will begin in electrical form, and that this must be converted to magnetic form by some injector device at one end of the stack. A suitable injector device will now be discussed with reference to FIGS. 16 and 17.

FIG. 16 shows a very simple form of an injector. The SAF stack 5 is fabricated on top of a short current-carrying strip line 30 on a CMOS integrated circuit. The two ends of the strip line are attached to metallic vias 32 which connect to transistors within the main body of the CMOS circuit. The transistors control current pulses 34 through the strip line, which in turn generate localised pulses of magnetic field 36 which predominantly affect the magnetisation of the nearest layers of the SAF stack 5.

The strength of the magnetic field from a current-carrying strip line falls off above it on a lengthscale approximately equal to the width of the strip line itself. For a stack having a 10 nm repeat period for the stack, a 100 nm wide strip line would therefore generate a magnetic field across the first 10 repeat layers or so of the SAF, which is more than is desirable to inject a soliton from the end of the stack. However, the very end magnetic disk of the stack 5 is easier to switch magnetically than the others near it, since it only has one nearest neighbour disk providing a stabilising coupling field—all of the other disks (except the disk at the other end, which is too far away from the strip line to be influenced) have two stabilising nearest neighbours. By a correct choice of current amplitude to induce the pulse 34, it is possible for the current-carrying strip line to switch only the bottom magnetic disk even though the magnetic field from it extends higher up the stack.

As will be apparent from the above discussion, an injected soliton should be of the correct chirality to propagate up the stack for the chirality of rotating field in use (see Table above). The injector device therefore also controls the chirality of the injected soliton. According to the present examples, this can be achieved by careful choice of the direction of the local magnetic field generated by the strip line (effectively the orientation of the strip line with respect to the ellipse axes) and also careful choice of the timing of the strip line current pulse with respect to the externally applied rotating magnetic field phase.

If these conditions are controlled such that the strip line current is fired at the instant that the externally applied magnetic field is parallel to the direction of the strip line field, this maximises the strength of the field at the bottom disk since the externally applied field and the local strip line field are reinforcing each other to the maximum degree. In this circumstance, the two parameters that must be considered for successful injection are (i) magnitude of the current in the strip line and (ii) the phase angle of the externally applied rotating field at which the strip line is fired.

An example phase diagram which describes the behaviour of an injected soliton in dependence upon these parameters is shown in FIG. 17. The phase diagram defines an envelope 40 for these two parameters, inside of which the correct chirality of soliton will always be injected for propagation up the stack. The physical conditions which give rise to the values in the example phase diagram of FIG. 17 are: disk dimension 100 nm×70 nm×10 nm; disk saturation magnetisation 800 emu/cm³; spacer thickness 3 nm; strip line cross-section 200 nm×50 nm; external field strength 1500e; external field rotation sense clockwise as viewed from top of stack. It will be appreciated that the phase diagram is dependent upon all of these parameters and so may have a different shape and/or different dimensions relative to the phase angle and/or current magnitude for different parameter sets.

The power dissipated during the injection process by Joule heating of the stripline can be minimised by (i) using as short a current pulse as possible (typically of the order of 10 ns duration); (ii) using as low a frequency as possible for the external rotating field (thereby reducing the duty cycle of the strip line current); (iii) cladding the outside of the strip line with a magnetic material to concentrate the magnetic flux lines generated around it, as described in U.S. Pat. No. 6,724,652, the entire content of which is hereby incorporated hereinto by reference.

Thus a mechanism and example arrangement for introducing solitons into a SAF stack have now been described. As will be appreciated from the foregoing, a significant use of this technique is for data storage. In the following, a mechanism and example arrangement for reading solitons from such a SAF stack will now be described.

As mentioned above, the options for using a SAF stack having solitons introduced thereinto for data storage purposes are a First In First Out (FIFO) shift register (where reading occurs at the opposite end of the stack to writing) and a First In Last Out (FILO) shift register (where reading and writing occur at the same end of the stack).

The present example assumes that a First In Last Out (FILO) shift register is provided such that the data are injected into the bottom of the soliton stack and shifted up the stack during writing; for read-back, the rotating field is reversed and the data are shifted back down the stack and out of the bottom in reverse order). In this arrangement it is necessary to measure the magnetisation state of the lowest magnetic layer. Efficient methods to achieve this include a magnetoelectronic method to convert the magnetisation direction of the lowest magnetic layer into either a change in electrical resistance or a change in voltage. Methods for doing this include a giant magneto resistance spin valve and a tunnel magneto resistance structure.

The Giant Magneto Resistance (GMR) spin valve approach uses a technique described in, for example, U.S. Pat. No. 4,949,039, the entire content of which is hereby incorporated hereinto by reference. An example of a GMR spin valve structure as applied to the soliton storing SAF stack as described above is shown in FIG. 18.

This implementation uses the end magnetic layer 50 of the stack 5 closest to the reading/writing element 22 to form the free layer in a Giant Magneto Resistance spin valve 58. The GMR spin valve has four layers, a pinning non-magnetic layer 56, a pinned magnetic layer 54, a further magnetic layer 52 and the free layer 50 (provided by the end magnetic disk 50 of the stack 5). An electrical current is passed through the pinned magnetic layer 54 which is in electrical contact via the non-magnetic spacer 52 with the end magnetic disk 50 in the SAF stack 5. Some of the electrical current leaks between the pinned magnetic layer 54 and the bottom magnetic disk 50, leading to spin-dependent scattering and hence an electrical resistance for the combined circuit that depends on the relative orientation of the magnetisation in the bottom magnetic disk in the SAF stack and the magnetisation in the pinned magnetic layer.

The bottom layer 56 of the spin-valve structure 58 can double up as the current-carrying strip-line used for writing (see element 30 in FIG. 16).

The first non-magnetic spacer layer 51 within the SAF stack may be made from an electrical insulator to prevent current from leaking into higher magnetic layers in the SAF stack.

Thus the use of a GMR spin valve to write solitons into and read solitons out of a SAF stack has now been described.

An alternative reader structure based upon a Tunnel Magneto Resistance (TMR) structure will now be described. Such a structure provides a high usable magnitude of the read-out signal, thus enabling a high density arrangement of stacks on the circuit which supplies the data to the stacks (such as CMOS circuit 24). A TMR structure is more complex to fabricate than the GMR spin valve mentioned above, as it requires an electrical connection to be made above the bottom magnetic layer in the SAF. In this example the bottom of the SAF stack is isolated from a pinned ferromagnetic layer by a tunnel barrier (e.g. a thin magnesium oxide layer, see, for example, S. S. P. Parkin et. al. “Giant tunneling magnetoresistance at room temperature with MgO (100) tunnel barriers” Nature Materials 3, 862-867 (2004) doi:10.1038/nmat1256, the entire content of which is hereby incorporated hereinto by reference) and an electrical current is passed between the bottom magnetic layer of the SAF stack and the pinned ferromagnetic layer via the tunnel barrier. The TMR effect gives a very strong dependence of resistance on the relative orientation of the magnetisation in the two magnetic layers, allowing the magnetic state of the bottom of the SAF to be easily detected.

According to the present examples, the electrical current can either be localised to flow through only a small number of magnetic layers within the SAF by applying side-contacts to the SAF stack, or, it may flow through all of the magnetic layers within the SAF by applying a top-contact to the SAF (which can be easier to fabricate). If a top-contact approach is used, the magnetic detection can be localised to any point within the SAF stack by using electrically conducting non-magnetic spacer layers throughout the SAF stack, except at the point where the soliton is to be detected where a tunnel barrier layer is used instead. Even though many layers of the SAF stack are involved in the passage of the electrical current, the electrical resistance is dominated by the tunnel barrier and the spin-dependence of the resistance of the stack is dominated by the relative orientation of the magnetisation on either side of the tunnel barrier.

FIG. 19 shows an example implementation of this principle. The TMR structure 68 includes a pinning non-magnetic layer 66, a pinned ferromagnetic layer 64, a tunnel barrier layer 62 and the bottom magnetic disk 60 of the stack 5. In this example, the tunnel barrier 62 is placed between the bottom magnetic layer 60 of the SAF 5 and a pinned reference layer 64 outside of the SAF. The inter-disk spacer layers 69 of the stack 5 are provided from electrically conductive material which causes the electrical resistance through the structure a whole to be dominated by the tunnel barrier layer 62. This leads to an electrical resistance through the SAF which depends on the direction of magnetisation of the bottom magnetic layer 60 in the SAF.

FIG. 20 shows an example where the tunnel barrier 62 is placed between the bottom 60 and second from bottom 61 magnetic layers of the SAF 5 and there is no pinned reference layer outside of the SAF. Again the non-magnetic spacer layers of the stack (except the tunnel barrier layer 62) are of electrically conductive material. This leads to an electrical resistance through the device as a whole which depends on the relative orientation of the magnetisation in the bottom and second from bottom layers in the SAF. This would changes as a soliton passes through: when any soliton is far away these two layers have approximately 180° between their magnetisation (anti-parallel coupling); and when a soliton is across the tunnel barrier, these two layers have approximately 90° between their magnetisation. Thus this example provides for a transition detection rather than a state detector.

A further variation on this principle is shown in FIG. 21 where the tunnel barrier layer 62 is placed at the top of the stack between the top 60a and second from top 61a magnetic disks in the stack 5. As in FIG. 16, this allows transition detection of a soliton passing through the tunnel barrier. Because this detector is at the top of the SAF stack, data can be read out without reversing the sense of the externally applied rotating field, making a First In First Out (FIFO) shift register. This also allows data to be written and read at the same time.

In the described arrangements using a TMR detection system, the soliton injection arrangement is omitted for simplicity of understanding. A separate (or partially integrated) injection arrangement can use a strip line type arrangement as discussed above.

A variation on the TMR detection system which does not require the fabrication of a top contact involves forming a conventional magnetic tunnel junction (MTJ) stack, as is currently used for MRAM, and placing the SAF stack on top of the free layer, in full ferromagnetic contact as shown in FIG. 22. The MTJ is formed from a magnetic tunnel junction free layer 70, a non-magnetic tunnel barrier layer 72, a pinned ferromagnetic layer 74 and a pinning antiferromagnet 76. The bottom magnetic disk 60 of the stack is in full ferromagnetic contact with the MTJ free layer 70.

In this arrangement, no electrical current passes through the SAF stack 5 itself and the output is determined purely by the relative orientation of the magnetisation in the MTJ free layer 70 and the magnetisation in the MTJ pinned layer 74. However, the ferromagnetic contact between the MTJ free layer 70 and the magnetic layer 60 at the bottom of the SAF stack results in strong coupling between the magnetic state of the free layer 70 and the bottom disk 60 of the SAF stack 5. Thus whenever a soliton switches the bottom disk 60 of the SAF stack 5, the free layer 70 of the MTJ also switches. Preferably the free layer of the MTJ should be thinner than the bottom magnetic layer of the SAF for optimum performance.

It will be appreciated that although the stacks shown in the example devices of FIGS. 15, 16, 18, 19, 20, 21, 22 include only a small number of layers in the stack 5, this is for the purposes of making the figures clear and easily understandable, and, as discussed above, each stack may include a much larger number of layers, for example 100 to 100,000 or even more layers.

It will be appreciated that arrangements could be constructed with reading elements at both ends to facilitate use as a FIFO and a FILO shift register. Reading and/or writing elements could also be placed at a location other than the end of a stack. One example of such an arrangement could have reading and writing elements in the middle of the stack, so as to provide that data is written when applying a rotating magnetic field in a first direction to enable half of the stack to be used for storage. Data would then be read by reversing the magnetic field direction. However the presence of the read element in the middle of the stack could provide that, if a non-destructive read-method is utilised, the stored solitons pass into the second half of the stack and thus are maintained in memory after reading. In this way a persistent memory can be provided where reading the data does not cause deletion thereof.

Thus a number of examples of SAF stack structures enabling the writing of solitons thereinto and the reading of solitons therefrom have now been described. A large number of different data storage devices can be implemented using such structures and including any number of individual stacks.

As is mentioned above, solitons injected into and propagated through a SAF stack can be used to store data bits using the SAF stack as a shift register. More than one data coding scheme can be implemented to enable such data storage and examples thereof will now be discussed.

Monte Carlo macrospin modelling shows that solitons of the same chirality repel each other upon close approach, which acts to prevent data sequences from collapsing. As discussed above, it is expected that all of the solitons in a SAF stack will be of the same chirality so that they all propagate under an applied rotating field in the same direction.

Data sequences can be coded in a number of different ways, including:
using the presence or absence of a soliton to represent the data bit value; or
using the order parameter of the antiferromagnetic coupling (described above with reference to FIG. 4) to represent the data bit value such that a soliton represents transition from one data value to another.

FIG. 23 shows an example of how the same magnetic configuration in a SAF stack can be interpreted in two different ways, depending on which of the above coding schemes is used. The left hand column (labelled “A”) uses the presence or absence of a soliton to represent the data value. The right hand column (labelled “B”) uses the order parameter to represent the data value with solitons providing a bit value transition.

It will be appreciated that these two coding schemes differ in the phase of the data sequence, (although the particular choice of definitions used in FIG. 23 has also led to an inversion) since the presence of a soliton always leads to a change in the order parameter of the following domain.

Monte Carlo macrospin modelling shows that there is a minimum spacing that may exist between neighbouring solitons. This is particularly the case for injecting solitons with controlled chirality—the phase diagram of FIG. 17 only works if there is not a soliton in the vicinity of the end zone of the SAF stack. The number of bits that can be stored in one SAF stack is given roughly by the number of repeat layers in the stack divided by the number of layers that must be assigned to each soliton. Careful tuning of the anisotropy and coupling strength can be used to minimise the minimum spacing between solitons and hence maximise the storage density. This is usually at the expense of the operating margin (i.e. the difference between the nucleation field/maximum propagation field and the propagation field) and a balance must be found that gives a high enough storage density while retaining robustness against manufacturing variations in the SAF stack.

In the examples described above, each soliton requires a minimum of four magnetic disks leading to a maximum data density of ¼ times the number of repeat layers in the SAF stack. If an arrangement were implemented which required five magnetic disks per soliton, the maximum data density would become ⅕ times the number of repeat layers in the SAF stack.

Thus there have now been described a number of approaches for encoding data onto a SAF stack using introduced and propagated chiral solitons in the stack.

Methods for fabrication of the arrangements described above will now be considered.

Viewed in one way, in terms of fabrication, the arrangements described herein can be considered to be a development from and extension of the fabrication approach for existing MRAM devices, particularly in the case of the detection schemes of FIGS. 19 and 20. The main change to the fabrication is to increase the number of repeat layers of the SAF. Using the understanding of introducing, propagating and detecting solitons provided above provides a minimal architectural change approach to increasing the number of magnetic bits that can be stored in an MRAM type device. Current MRAM devices have both a word-line and a bit-line at each single bit storage cell and use dephased current pulses between these two lines to generate a local rotating magnetic field. If the number of repeat layers in the SAF stack is not too high, the existing word-line and bit-line arrangements can be used to generate the rotating magnetic field for propagating the soliton as well as writing it where a lower amplitude field is used for propagating and a higher amplitude field for writing.

Viewed in another way, the arrangements described herein require a new fabrication method for forming high aspect-ratio SAF stacks. Conventional lithographic methods of using high vacuum vapour deposition such as sputtering to form continuous layers and then using lithography to fabricate a hard etch mask structured layer on top (e.g. silicon nitride) followed by etching (e.g. reactive ion etching or ion beam milling) to transfer the lithographic pattern into the multilayered film stack could be used. Alternatively, a templating method could be used in which hollow pores are formed in a matrix and then electrodeposition is used to fill the pores with the metal layers. The pores could be formed by the X-ray LIGA method, by electrical anodising or by imprint nanolithography.

Thus it will be understood that while the fabrication of devices incorporating the arrangements describe above may appear superficially similar to convention MRAM fabrication approaches, the significantly higher data capacity provided by the present examples leads to alterations in the method of usage of conventionally fabricated elements and/or the methodology of fabrication.

Related to the consideration of formation of the stack and associated reading and writing elements is the matter of applied field generation. As is mentioned above, for a small stack on a convention bit-line/word-line matrix, the applied field can be applied using low magnitude dephased pulses on these lines. For such arrangements, and for arrangements where this is not technically possible due to the design of the bit-lines and word-lines or the size of the stack, other approaches can be considered.

An efficient way to generate the rotating magnetic field that propagates solitons through the SAF stack is by a pair of current carrying conductors oriented at right angles to each other. Various embodiments can be used to implement such a system, including:
a pair of coplanar waveguides, as described in P. Martin Pimentel et. al. “A new crossed coplanar waveguide design for ultrafast magnetization switching utilizing polymer insulation layers”, Appl. Phys. Lett. 88, 122510 (2006) doi:10.1063/1.2186947 (the entire content of which is hereby incorporated hereinto by reference);
a pair of current-carrying strip lines fabricated either on the same chip as the data-storing SAF stacks, or on a separate chip that is flip-chip bonded to the data-storing SAF stack chip;
a pair of planar coils fabricated by MEMS technology, either on the same chip as the data-storing SAF stacks, or on a separate chip that is flip-chip bonded to the data-storing SAF stack chip;
two pairs of external coils; or
two pairs of external coils wrapped around a ferrite ring

The two field generators may be powered by a cosine and sine wave of current, thus forming a rotating field. However, in order to reduce power dissipation, they may also be powered by orthogonal current pulses Hₓ and H_{y} as shown in FIG. 24, since soliton propagation does not require a smooth rotation of applied field.

Thus there have now been described a number of examples for generation of a rotating magnetic field to drive the propagation of solitons through a SAF stack.

It will be appreciated that reference herein to the “top” or “bottom” of elements such as the stack are references to the orientations shown in the Figures and that the devices and arrangements described herein may be inverted or tilted by any angle in any plane without affecting the operation thereof and thus the “top” and “bottom” can be considered as ends according to the particular orientation of the device at a given time.

The skilled reader will appreciate that the various described arrangements for a column of magnetostatically coupled magnetic discs which can maintain an introduced soliton therein and have that soliton propagated therethrough by an externally applied rotating magnetic field and have solitons written thereinto and read therefrom are examples which illustrate the concepts underlying the present invention. Various modifications, alterations and equivalents may be employed without departing from the spirit and scope of the present invention.

1. A magnetic memory structure comprising:
a column comprising a plurality of layers of magnetic material, each sized to adopt a single magnetic domain state, and a plurality of layers of non-magnetic material arranged as spacer layers between adjacent ones of the layers of magnetic material; such that successive magnetic layers in the column are magnetically antiparallel coupled;
such that the column is operable to maintain therein a plurality of stable transitions of an order parameter of the magnetisations between the magnetic layers, the transitions having a chirality.

2. The structure of claim 1, wherein the transitions create a plurality of regions within the column, each region having an order parameter opposite to the order parameter of an adjacent region.

3. The structure of claim 1, wherein the column comprises between 100 and 100,000 magnetic layers.

4. The structure of claim 1, wherein each stable transition is a soliton.

5. The structure of claim 4, wherein the soliton is a topological soliton.

6. The structure of claim 5, wherein the topological soliton is a kink soliton.

7. The structure of claim 1, further comprising an arrangement operable to introduce a transition into the column.

8. The structure of claim 7, wherein the arrangement comprises a charge pulse conduit arranged parallel and adjacent to an end magnetic layer in the column operable to carry an electrical charge pulse therethrough.

9. The structure of claim 8, further comprising a drive element operable to cause a charge pulse to travel through the charge pulse conduit whilst a rotating magnetic field is applied to the column.

10. The structure of claim 9, further comprising an arrangement operable to read a transition from the column.

11. The structure of claim 10, wherein the arrangement to read a transition uses at least one of a giant magneto resistance spin valve, a tunnel magneto resistance structure, and a magnetic tunnel junction stack.

12. The structure of claim 10, wherein the arrangement to read a transition is arranged such that the transition is maintained in the column after reading thereof.

13. The structure of claim 10, further comprising an arrangement operable to introduce a transition into the column, wherein the placement of the arrangement to introduce a transition into a column and the arrangement to read a transition from the column is such as to enable operation of the structure as a first in first out shift register.

14. The structure of claim 10, further comprising an arrangement operable to introduce a transition into the column, wherein the placement of the arrangement to introduce a transition into a column and the arrangement to read a transition from the column is such as to enable operation of the structure as a first in last out shift register.

15. The structure of claim 1, wherein the magnetically antiparallel coupling between successive magnetic layers in the column causes the magnetisations of successive magnetic layers in the column to be antiparallel aligned except where the alignment is forced to be non-antiparallel by the presence of a transition.

16. A magnetic memory circuit comprising:
at least one structure according to claim 1; and
a signal supply conduit operable to carry a write signal to or read signal from the structure.

17. The circuit of claim 16, wherein a plurality of structures are provided and wherein the signal supply conduit comprises an arrangement to address individual ones of the plurality of structures.

18. A magnetic memory device comprising:
the circuit of claim 16; and
a magnetic field generator operable to generate a rotating magnetic field.

19. The device of claim 18, wherein the magnetic field generator comprises a configuration to supply a filed inducing signal to the signal supply conduit.

20. The device of claim 19, wherein the magnetic field generator comprises a pair of current carrying conductors oriented substantially orthogonally to one another.

21. A method of storing data within a memory structure comprising a plurality of layers of magnetic material, each sized to adopt a single magnetic domain state, and a plurality of layers of non-magnetic material arranged as spacer layers between adjacent ones of the layers of magnetic material; such that successive magnetic layers in the column are magnetically antiparallel coupled, the method comprising:
introducing into the column a plurality of stable transitions of an order parameter of the magnetisations between the magnetic layers, the transitions having a chirality, wherein data is encoded using the transitions.

22. The method of claim 21, wherein the data is encoded using one of: an order parameter state, or a presence or absence of an order parameter transition to represent data values.

23. The method of claim 21, wherein the column comprises between 100 and 100,000 magnetic layers.

24. The method of claim 21, wherein each transition is a soliton.

25. The method of claim 24, wherein the soliton is a topological soliton.

26. The method of claim 25, wherein the topological soliton is a kink soliton.

27. The method of claim 21, further comprising introduce a transition into the column by passing a charge pulse through a charge pulse conduit arranged parallel and adjacent to an end magnetic layer in the column.

28. The method of claim 21, further comprising reading a transition from the column using at least one of a giant magneto resistance spin valve, a tunnel magento resistance structure, and a magnetic tunnel junction stack.

29. The method of claim 28, further comprising maintaining the transition in the column after reading.

30. The method of claims 21, further comprising operating the column as a first in first out shift register.

31. The method of claim 21, further comprising operating the column as a first in last out shift register.

32. The method of claim 21, further comprising applying an externally generated rotating magnetic field to the column to cause propagation of chiral transitions along the column.

33. The method of claim 32, further comprising generating the rotating magnetic filed using a pair of current carrying conductors oriented substantially orthogonally to one another.

34. The method of claim 21, wherein the magnetically antiparallel coupling between successive magnetic layers in the column causes the magnetisations of successive magnetic layers in the column to be antiparallel aligned except where the alignment is forced to be non-antiparallel by the presence of a transition.

35. Apparatus comprising a stack of magnetically antiparallel coupled magnetic elements wherein successive ones of the magnetic elements are arranged such that the easy axis of anisotropy of each magnetic element is parallel to that of neighbouring magnetic elements such that a lowest energy state of the stack is antiparallel magnetic coupling between successive magnetic elements and such that a stable frustration in magnetisation alignment can be maintained across a plurality of successive magnetic elements, the frustration giving rise to a chiral soliton in magnatisation direction within the stack.

36. Apparatus comprising a stack of overlapping synthetic antiferromagnets wherein successive layers of magnetic material within the stack are arranged such that the easy axis of anisotropy of each layer of magnetic material is parallel to that of neighbouring layers of magnetic material such that a lowest energy state of the stack is antiparallel magnetic coupling between successive layers of magnetic material and such that a stable frustration in magnetisation alignment can be maintained across a plurality of successive layer of magnetic material, the frustration giving rise to a chiral soliton within the stack.
